(19) United States
(12) Patent Application Publication
(10) Pub. No.: US 2009/0189240 A1
(43) Pub. Date: Jul. 30, 2009

(54) SEMICONDUCTOR DEVICE WITH AT LEAST ONE FIELD PLATE

(75) Inventors: Armin Willmeroth, Augsburg (DE); Anton Mauder, Kolbermoor (DE); Michael Rueb, Faak am See (DE); Franz Hirler, Isen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AUSTRIA AG, Villach (AT)

(21) Appl. No.: 12/019,759

(22) Filed: Jan. 25, 2008

(51) Int. Cl. H01L 23/58; H01L 21/76

(52) U.S. Cl. 257/488; 438/454; 257/E23.002; 257/E21.54

(57) ABSTRACT

A semiconductor component with at least one field plate. One embodiment provides the field plate to make contact with the semiconductor body at a connection contact. The semiconductor body has in the region of the connection contact a doping concentration that is less than 5·10¹⁷ cm⁻³.

### BACKGROUND

Field plates are used in semiconductor components, in particular in power semiconductor components. The field plates are for example part of an edge termination and serve to influence the field line profile of an electric field that occurs in the semiconductor component during operation. In this way, when an overvoltage occurs, it is possible to prevent voltage breakdowns at specific locations in the semiconductor body of the component, for example in the edge region. Field plates arranged above a side of the semiconductor body additionally serve to protect the semiconductor body against external influences, for example against electrical charges (usually in the form of ions).

Such field plates are usually connected to the semiconductor body using an ohmic contact, thereby achieving the effect that the field plate is at the same electrical potential as the semiconductor body in the region to which the field plate is connected. In order to obtain an ohmic contact between the field plate and the semiconductor body, a highly doped semiconductor zone to which the field plate is connected must be present in the semiconductor body. However, such highly doped semiconductor zones are costly in terms of space, that is to say that they cannot be produced with arbitrarily small dimensions. One reason for this is unavoidable diffusion processes that cause dopants that are introduced into the semiconductor body for producing the highly doped zone to be indiffused further than would be necessary for the realization of an ohmic contact. In the case of components having a relative high blocking capability, diffusion times in connection with the production of active component regions are relatively long, whereby an indiffusion of the dopants of the abovementioned highly doped semiconductor zone is also intensified. In addition, this effect is all the more pronounced, the higher the intended doping of the highly doped zone.

### SUMMARY

One embodiment described below relates to a semiconductor component including a semiconductor body and at least one field plate which makes contact with the semiconductor body at a connection contact, and in which the semiconductor body has in the region of the connection contact a doping concentration that is less than 5·10¹⁷ cm⁻³.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates an extract from a cross section through a semiconductor body of a semiconductor component including a field plate coupled to the semiconductor body.

FIG. 2 illustrates a field plate which is modified in comparison with the field plate in accordance with FIG. 1.

FIG. 3 illustrates a further field plate which is modified in comparison with the field plate in accordance with FIG. 1.

FIG. 4 illustrates a coupling of a field plate to a semiconductor body by using a Schottky contact.

FIG. 5 illustrates an extract from a cross section through a semiconductor body of a semiconductor component including a plurality of field plates coupled to the semiconductor body.

FIG. 6 illustrates by way of example a semiconductor component which is formed as a power transistor and which includes a field plate coupled to a semiconductor body.

FIG. 7 illustrates a plan view of a semiconductor body of a semiconductor component including at least one field plate.

FIG. 8 illustrates a plan view of a semiconductor body of a further semiconductor component including at least one field plate.

FIG. 9 illustrates the coupling of a field plate to a semiconductor body by using its tunnel oxide.

FIG. 10 schematically illustrates a semiconductor component including a semiconductor body, a field plate and a voltage limiting arrangement arranged between the field plate and the semiconductor body.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

FIG. 1 illustrates an extract from a vertical cross section through a semiconductor body 100 of a semiconductor component. The semiconductor body 100 has a first side 101, which is referred to hereinafter as front side, and an edge side 102. In the example in accordance with FIG. 1, the edge side 102 runs perpendicular to the front side 101, but can also run in beveled fashion with respect to the front side 101, or—in the case of planar components—can run parallel to the front side 101. FIG. 1 only illustrates the edge region of the semiconductor body, that is to say the region adjacent to the edge side 102 in a lateral direction of the semiconductor body 100. Active component regions of the semiconductor component, that is to say doped semiconductor zones which determine the actual function of the semiconductor component, are not illustrated in the figure.

The semiconductor body 100 has a first doped semiconductor zone 11, which, in the extract illustrated, extends as far as the front side 101 and as far as the edge side 102 of the semiconductor body 100. The first semiconductor zone 11 can be part of a semiconductor substrate having a basic doping, or part of a semiconductor layer having a basic doping, for example an epitaxial layer. A doping concentration of the first semiconductor zone 11 is for example below 5·10¹⁷ cm⁻³, in one embodiment below 5·10¹⁶ cm⁻³ or 10¹⁶ cm⁻³, and can even be below 10¹⁵ cm⁻³.

The component additionally has a field plate 20, which is coupled to the semiconductor body 100 at the front side 101. In the example illustrated, the field plate 20 directly makes contact with the semiconductor body 100 in the region of the front side 101, such that a connection contact 13 is formed between the field plate 20 and the semiconductor body 100. In one variant, the field plate 20 makes contact with the first semiconductor zone 11 in this case. In a second variant, the field plate 20 makes contact with a second semiconductor zone 12 (illustrated in dashed fashion), which is doped complementarily to the first semiconductor zone 11, is arranged in the first semiconductor zone 11 and is adjacent to the front side 101. In this case, a net doping concentration of the second semiconductor zone 12 is less than 5·10¹⁷ cm⁻³ and for example less than 5·10¹⁶ cm⁻³ or even less than 10¹⁶ cm⁻³. In this case, “net doping concentration” denotes the effective doping concentration of dopants of the conduction type corresponding to the conduction type of the second semiconductor zone. Merely for explanation purposes it is assumed for the example embodiment according to FIG. 1 that the second semiconductor zone 12 is a p-doped semiconductor zone and the first semiconductor zone 11 is an n-doped semiconductor zone. It goes without saying that the doping types of these semiconductor zones could also be interchanged.

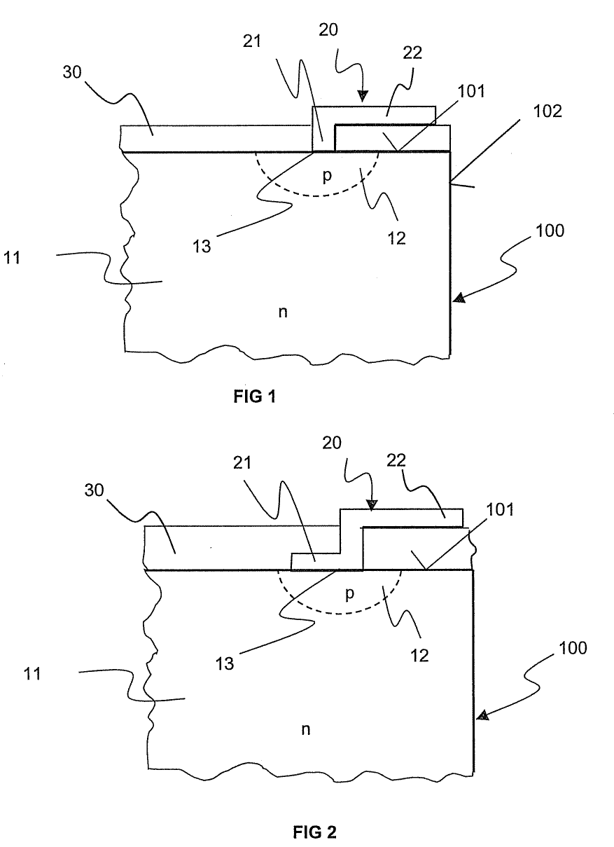

The field plate 20 illustrated in FIG. 1 has a first plate-type section 22, which is arranged at a distance from the front side 101, and a contact section 21, which is adjacent to the first plate-type section 22 and makes contact with the semiconductor body 100. In the example embodiment illustrated in FIG. 1, the contact section 21 runs substantially perpendicular to the first plate-type section 22. Referring to FIG. 2, the contact section 21, for enlarging the contact area, can have a second plate-type section, which runs parallel to the front side 101 and which makes contact with the semiconductor body 100.

On account of the low doping of the semiconductor body 100 in the region of the connection contact 13, independently of the material of the field plate 20, there is no ohmic contact between the field plate 20 and the semiconductor body 100. Instead, one example embodiment provides for producing a Schottky contact between the field plate 20 and the semiconductor body 100. For this purpose, the field plate 20 is composed, for example, completely of a material suitable for forming such a Schottky contact, such as, for example, platinum (Pt), platinum silicide (PtSi), gold (Au), palladium silicide (PdSi), rhodium silicide (RhSi), nickel silicide (NiSi) or tungsten silicide (WSi₂). Such materials are referred to hereinafter as Schottky metals.

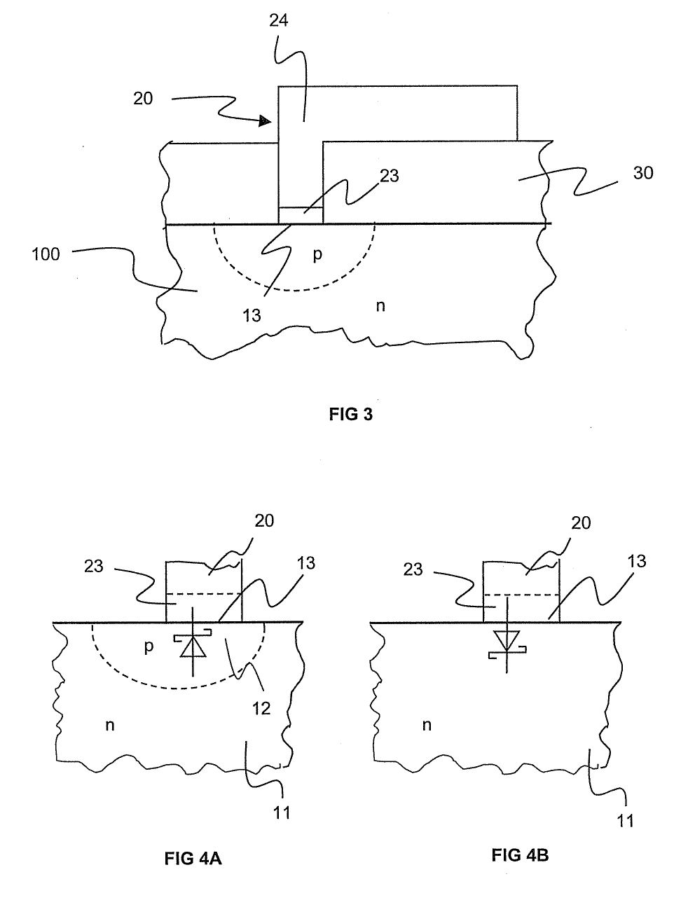

Instead of producing the entire field plate 20 from a Schottky metal, there is also the possibility, referring to FIG. 3, of providing a Schottky metal 23 only in the region of the connection contact 13 and of producing remaining regions 24 of the field plate 20 from another electrically conductive material, such as, for example, a further metal or a doped polycrystalline semiconductor material, in one embodiment doped polysilicon. Further metals for the remaining region 24 of the field plate are for example aluminum (Al) or copper (Cu).

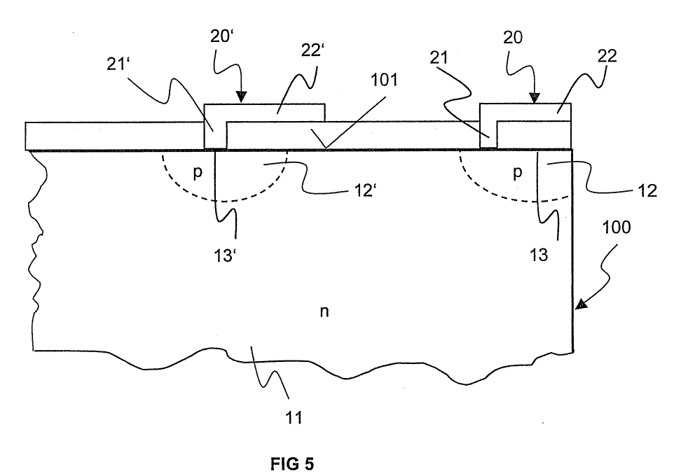

The realization of the connection contact 13 between the field plate 20 and the semiconductor body 100 as a Schottky contact is equivalent to a Schottky diode being present between the field plate 20 and the semiconductor body 100. In this case, the polarity of the Schottky diode is dependent on the doping type of the semiconductor body 100 in the region of the connection contact 13. FIG. 4A illustrates the polarity of the Schottky diode for the case where the field plate 20 makes contact with a p-doped semiconductor region of the semiconductor body 100. The Schottky diode, the electrical circuit symbol of which is illustrated in FIGS. 4A and 4B, is in this case reverse-biased between the field plate 20 and the semiconductor body 100. The electrical potential of the field plate 20 can thereby rise above the value of the electrical potential of the semiconductor body 100 in the region of the connection contact 13. In this case, a potential difference between the field plate 20 and the semiconductor body 100 is limited by the breakdown voltage of the Schottky diode, which can lie for example in the range of a few tens of volts.

If the semiconductor body in the region of the connection contact 13 is n-doped, then the Schottky diode is reverse-biased from the semiconductor body to the field plate 20. As a result, the electrical potential of the semiconductor body in the region of the connection contact 13 can rise above the electrical potential of the field plate 20, a maximum potential difference being limited by the breakdown voltage of the Schottky diode in this case, too. In both cases the breakdown voltage of the Schottky diode is dependent, inter alia, on the doping concentration of the semiconductor body in the region of the connection contact 13 and is all the higher the lower the doping concentration.

Instead of a Schottky metal, the field plate 20 can also be composed completely, or at least in the region of the connection contact 13, of a highly doped polycrystalline semiconductor material, such as polysilicon for example. The doping concentration of this highly doped polycrystalline material is above 10¹⁹ cm⁻³, for example. In this case, there is present between the field plate 20 and the semiconductor body a diode which admittedly does not have ideal diode properties—it has high leakage currents, inter alia—on account of the different materials at the pn junction, but limits the potential difference between the field plate 20 and the semiconductor body 100 upwardly to a few tens of volts.

FIGS. 1 to 3 illustrate in each case only one field plate for the purpose of elucidating the basic principle. It goes without saying that the component can have a plurality of field plates which are arranged at a distance from one another in a lateral, or horizontal, direction of the semiconductor body 100 and which are coupled to the semiconductor body 100.

FIG. 5 illustrates a cross section through the semiconductor body 100 of a semiconductor component having a plurality, two in the example, of such field plates 20, 20′, which make contact with the semiconductor body 100 in the region of connection contacts 13, 13′. In accordance with the previous explanations, the field plates 20, 20′ can directly make contact with the first semiconductor zone 11. Optionally, the semiconductor body 100 can have in the region of the connection contacts 13, 13′ second semiconductor zones 12, 12′ which are doped complementarily to the first semiconductor zone 11 and which are arranged at a distance from one another in a lateral direction.

To afford a better understanding of the functioning of the field plate arrangements explained up to this point with reference to FIGS. 1 to 5, FIG. 5 illustrates a pn junction between the first semiconductor zone 11 and a third semiconductor zone 16, which is doped complementarily to the first semiconductor zone 11 and which is present in the components of FIGS. 1 to 4, too, but its illustration was omitted therein. Such a pn junction is present in any power semiconductor components, for example between the body zone and the drift zone of a MOSFET or IGBT, one of the anode or cathode zone and the base zone of a diode or p-type base and the n-type base of a thyristor. Even though these components differ in principle with regard to their electrical behavior in the turned-on state, these components nevertheless share the common feature that, in the off state, a space charge zone propagates in the semiconductor body proceeding from the pn junction, the space charge zone bringing about an electric field in the semiconductor body. Equipotential lines of such an electric field are illustrated by way of example by dash-dotted lines in FIG. 5.

The pn junction is usually situated in an inner region 103 of the semiconductor body 100 and thus ends in a lateral direction of the semiconductor body 100 before the edge region, which is designated by the reference symbol 104 in FIG. 5. Owing to the fact that the pn junction ends before the edge region 105, the equipotential lines run in curved fashion in the edge region 105 and reach as far as the front side 101 there. The field plates 20, 20′ serve, in a manner known in principle, to influence the profile of the electric field, or the potential profile, in the edge region 105 to the effect that higher electric field strengths than in the inner region 103 do not occur in the edge region 105, thereby preventing a situation in which, when a maximum reverse voltage of the component is reached, the location of a voltage breakdown lies in the inner region 103 and not in the edge region 105. The influencing of the potential profile in the edge region 105 is achieved by the plate-type geometry of the field plates 20, 20′ and the electrical coupling of the field plates 20, 20′ to the semiconductor body 100. In this case, the field plates 20, 20′ are at an electrical potential that is dependent on the respective electrical potential of the semiconductor body 100 in the region of the connection contact 13, 13′. If for example the electrical potential in the semiconductor body 100 increases along the front side 101 proceeding from the edge side 102 in a direction of the pn junction, then the electrical potential of the field plates 20, 20′ arranged successively in a lateral direction proceeding from the edge side 102 rises in a corresponding manner from field plate to field plate. A potential difference between the electrical potential of the respective field plates 20, 20′ and the electrical potentials of the semiconductor body 100 in the region of the connection contacts 13, 13′ is dependent in this case—in a manner already explained—on the type of the respective connection contact.

Although the connection of the field plates 20, 20′ to lightly doped semiconductor zones of the semiconductor body 100 can promote potential differences between the field plates 20, 20′ and the semiconductor body 100, edge constructions with such field plates connected to lightly doped semiconductor regions, in contrast to edge constructions with field plates connected to a semiconductor body via ohmic contacts, can be realized in a manner that saves a great deal of space, as is explained briefly below: in order to realize ohmic contacts, highly doped semiconductor zones to which the field plates are to be connected would have to be provided in the semiconductor body. In order to achieve a situation in which field plates that are arranged at a distance from one another in a lateral direction assume the electrical potential of the semiconductor body in the region below the field plates, the highly doped connection zones of the individual field plates must not touch one another, that is to say that they must be arranged in each case at a distance from one another. On account of unavoidable diffusion processes, however, such highly doped connection zones can only be realized in a costly manner in terms of space, which adversely affects the entire space requirement of the edge construction.

In the case of the edge or field plate constructions explained in which the field plates directly make contact with the first semiconductor zone 11 having a basic doping or lightly doped semiconductor zones 12, such space problems do not exist. In one embodiment, there is no need to comply with a mutual distance between the second semiconductor zones 12, 12′—if such second semiconductor zones are intended to be used for the contact-connection of the field plates. On account of their low doping, the second semiconductor zones 12 are fully depleted in the off-state case, that is to say in the case of a propagating space charge zone, thereby ensuring that the field plates arranged successively in a lateral direction are at different electrical potentials even if the second semiconductor zones 12, 12′ touched one another.

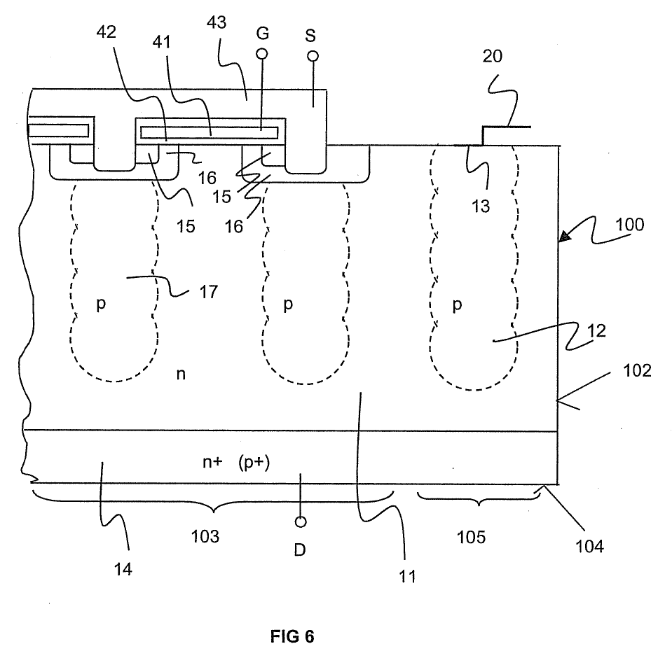

Referring to FIG. 6, the field plate constructions explained above are suitable in one embodiment for use in a semiconductor component formed as a power MOS transistor. FIG. 6 illustrates a vertical cross section through such a semiconductor component. For elucidation purposes, only one field plate 20 is illustrated schematically in the edge region of this semiconductor component. It should be noted in this context that it is also possible, of course, to provide a plurality of field plates arranged at a distance from one another in a lateral direction. The field plate 20 is only illustrated schematically in FIG. 6. This field plate or the field plates of this component can have any of the field plate geometries explained above and can be connected to the semiconductor body 100 via any of the contacts explained previously and contacts that will be explained below.

In the case of the component illustrated in FIG. 6, the first semiconductor zone 11 forms a drift zone. Adjacent to this drift zone 11 in a direction of a rear side 104—opposite the front side 101—of the semiconductor body 100 is a drain zone 14, which is doped more highly than the drift zone 11. The drain zone 14 is of the same conduction type as the drift zone in the case of a MOS transistor formed as a power MOSFET and is doped complementarily to the drift zone in the case of a MOS transistor formed as a power IGBT. In this case, the doping type specified between parentheses in FIG. 6 relates to an IGBT. In a manner not illustrated more specifically, in the case of an IGBT, a field stop zone which is of the same conduction type as the drift zone 11 but is doped more highly than the drift zone 11 can be provided between the drift zone 11 and the drain zone 14.

The MOS transistor additionally has a source zone 15, which is of the same conduction type as the drift zone 11 and with which contact is made by a source electrode 43. Arranged between the source zone 15 and drift zone 11 is a body zone 16, which is doped complementarily to the source zone 15 and the drift zone 11 and with which contact is likewise made by the source electrode 43. For controlling a conducting channel in the body zone 16 between the source zone 15 and the drift zone 11, the transistor additionally has a gate electrode 41, which is insulated from the semiconductor body by a gate dielectric 42 and which is arranged adjacent to the body zone 16. In the example illustrated, the gate electrode 41 is realized as a planar electrode and is therefore arranged above the front side 101 of the semiconductor body 100. In a manner not illustrated more specifically, the electrode could also be realized as a trench electrode arranged in a trench extending into the semiconductor body in a vertical direction.

The inner region 103 of the semiconductor body 100, in which the source and body zones 15, 16 are arranged, is also referred to hereinafter as active component region of the semiconductor body 100. The transistor illustrated can be constructed in cellular fashion, that is to say that it can have a multiplicity of component structures of identical type each having a source zone 15 and a body zone 16, wherein contact is made with the individual source zones 15 by a common source electrode 43 and wherein conducting channels in the individual body zones are controlled by a common gate electrode 41. Furthermore, the drain zone 14 is common to all the transistor cells. The individual transistor cells can be formed in strip-type fashion. In this case, the source and body zones 15, 16 run in strip-type fashion in a direction perpendicular to the plane of the drawing illustrated in FIG. 6. In a manner known in principle, however, the cells can also be realized as rectangular or arbitrarily polygonal cells, in one embodiment as hexagonal cells.

A modified transistor cell can be present in the transition to the edge region 105, which cell is modified in comparison with the rest of the transistor cells in such a way that no source zone is present in the region of the body zone 16 which is arranged in a direction of the edge region 105.

The transistor optionally has compensation zones 17 which are adjacent to the body zones 16, which are arranged in the drift zone 11 and which are doped complementarily to the drift zone 11. A semiconductor component having such compensation zones is also referred to as a compensation component. If the component is turned off, that is to say if a voltage that reverse-biases the pn junction between the body zone 16 and the drift zone 11 is present between a drain terminal D making contact with the drain zone 14 and a source terminal S making contact with the source electrode 43, then a space charge zone propagates in the drift zone 11 proceeding both from the body zone 16 and from the compensation zones 17. Dopant charges present in the compensation zones 17 and the drift zone 11 mutually compensate for one another in this case, wherein the dopant charges can be coordinated with one another in such a way that the dopant charges of the compensation zones 17 and of the drift zone 11 mutually compensate fully for one another.

A semiconductor zone having the same dimensions and the same doping as the compensation zones 17 can also be provided in the edge region 105 of the semiconductor body 100. This semiconductor zone can then serve as a second connection zone 12 for connecting the field plate 20. In a manner not illustrated more specifically, in the edge region it is possible, of course, to provide a plurality of such semiconductor zones which are arranged at a distance from one another in a lateral direction and to which a respective field plate is connected.

The first semiconductor zone or drift zone 11 is for example part of an epitaxial layer in which the source and body zones 15, 16 and the compensation zones 17 are produced by method steps which are known in principle. In this case, the doping of the first semiconductor zone or drift zone 11 corresponds to a basic doping of the epitaxial layer. The epitaxial layer is applied for example on a semiconductor substrate which is doped more highly and which forms the drain zone 14.

The transistor illustrated in FIG. 6 is an n-conducting transistor. In this case, the source zone 15 and the drift zone 16 are n-doped, while the body zone is p-doped. It goes without saying that the concept explained can also be applied to a p-conducting transistor. In this case, the doping types illustrated in FIG. 6 should be correspondingly interchanged.

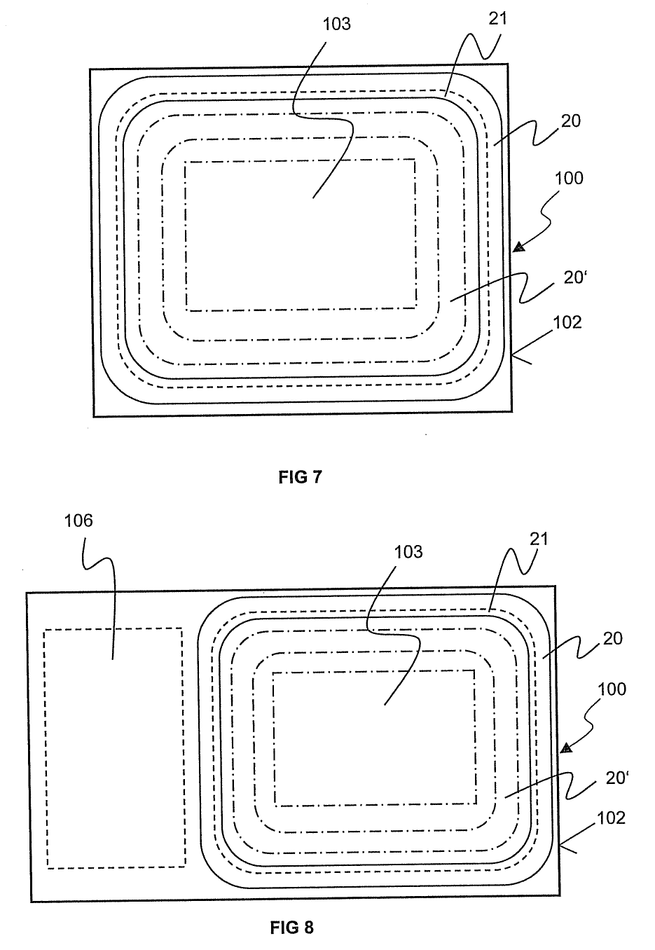

Referring to FIG. 7, the at least one field plate 20 can be realized in such a way that it runs in ring-shaped fashion above the front side 101 of the semiconductor body 100. FIG. 7 illustrates a plan view of this front side of the semiconductor body. The semiconductor body 100 illustrated is rectangular in plan view. In this case, a first field plate 20 illustrated in FIG. 7 extends along an edge of the semiconductor body and is formed in a manner to the geometry of the semiconductor body 100 as a rectangularly running ring whose corners are rounded. In this context, “edge” of the semiconductor body 100 should be understood to mean the border formed by the front side 101 and the edge side 102. Optionally, one or a plurality of further ring-shaped field plates can be provided within the first ring-shaped field plate 20. The reference symbol 20′ in FIG. 7 designates such a further field plate. The at least one field plate 20 surrounds the inner region or active component region 103 of the semiconductor component in ring-shaped fashion.

A connection region 21 of the field plate 20 is illustrated in dashed fashion in FIG. 7, the field plate 20 being connected to the semiconductor body 100 via the connection region. The connection region can extend over the entire length (running in ring-shaped fashion) of the field plate 20, as is illustrated in FIG. 6. Furthermore, the field plate 20 can also be realized in such a way that it makes contact with the semiconductor body 100 only in sections, for example only in the region of the corners running in rounded fashion, or for example only in regions outside the corners.

Referring to FIGS. 1 to 3 and 5, the field plate apart from the connection regions can be electrically insulated from the semiconductor body 100 by a passivation layer 30. The passivation layer can have contact holes into which the field plate extends as far as the semiconductor body 100 and makes contact with the semiconductor body there. Such a field plate can be produced for example by etching into the passivation layer 30 one or a plurality of openings in the region of which the later field plate is intended to make contact with the semiconductor body, and by subsequently depositing a material suitable for producing the field plate in the openings and above the passivation layer, the material subsequently being suitably patterned. In order to produce a field plate that was explained with reference to FIG. 3 and has regions composed of different materials, different materials can be deposited successively, for example firstly a Schottky metal and afterward a further electrically conductive material.

Referring to FIG. 8, the at least one field plate 20 need not necessarily run along the edge of the semiconductor body. Thus, by way of example, there is the possibility of realizing the field plate in such a way that it surrounds the active component region 103, that is to say the component region in which active component zones of a power semiconductor component are arranged, in ring-shaped fashion but that between the field plate 20 and the edge of the semiconductor body there is also arranged at least one further component zone 106 in which for example logic components, such as for example components for realizing a drive circuit for the power component, are integrated.

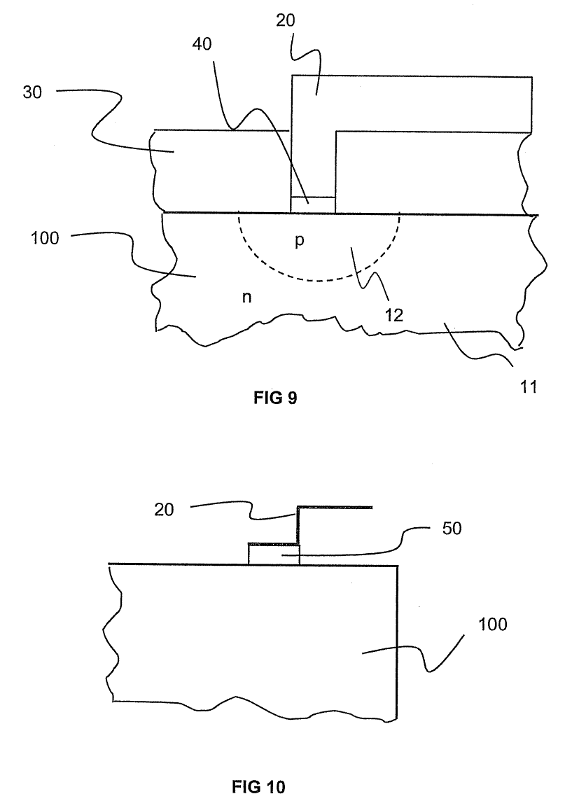

For the explanations above it was assumed that, for limiting a potential difference between an electrical potential of the at least one field plate 20 and the semiconductor body 100, a Shottky contact or a Schottky diode is present between the field plate 20 and the semiconductor body 100. In order to upwardly limit a potential difference between the field plate or the plurality of field plates and the semiconductor body 100, instead of a Schottky contact, referring to FIG. 9 it is also possible to arrange a tunnel dielectric 40 between the field plate 20 and the semiconductor body 100. In a manner corresponding to the explanations above, the tunnel dielectric 40 can be present in this case between the field plate 20 and the first semiconductor zone 11 or between the field plate 20 and a second semiconductor zone 12 that is optionally present and is doped complementarily to the first semiconductor zone 11. In connection with the present description, a “tunnel dielectric layer” should be understood to mean a dielectric layer, for example an oxide layer, which is dimensioned in such a way that it blocks voltages up to a maximum dielectric strength dependent on the dimensioning and enables a charge equalization for voltages higher than the maximum dielectric strength. In this case, a charge equalization through the tunnel dielectric layer takes place until the voltage difference falls below the maximum dielectric strength value. The tunnel dielectric layer 40 thus limits the potential difference between the field plate 20 and the semiconductor body 100 upwardly to a value defined by the maximum dielectric strength of the tunnel dielectric layer.

In principle, any desired voltage limiting arrangement 50 can be provided for limiting a potential difference between the field plate 20 and the semiconductor body 100, as is illustrated schematically in FIG. 10. This voltage limiting arrangement 50 can have a Schottky diode explained above, a tunnel dielectric explained above, a diode explained above with a polycrystalline semiconductor material, but can also have any further components suitable for limiting a potential difference.

In this context, “limiting a potential difference” should be understood to mean that a potential difference between the semiconductor body and the field plate does not exceed a predetermined value. This can be achieved for example by using components which have a voltage-dependent resistance that decreases upon a predetermined voltage value being exceeded, that is to say which have a nonlinear resistance characteristic curve. In this case the resistance characteristic curve describes the relationship between a voltage present across the component and the current flowing through the component.

The voltage limiting arrangement is dimensioned for example in such a way that it limits the voltage difference to values lying in the range of between 5% and 15%, in one embodiment in the region of 10%, of the desired dielectric strength of the component. In this case, the dielectric strength corresponds to the maximum permissible reverse voltage which is permitted to be applied to the component without a voltage breakdown occurring.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. (canceled)

2.-18. (canceled)

19. A semiconductor component comprising:
a semiconductor body;
at least one field plate which makes contact with the semiconductor body at a connection contact;
wherein the semiconductor body has in the region of the connection contact a doping concentration that is less than 5·10¹⁷ cm-3.

20. The semiconductor component of claim 19, comprising wherein the doping concentration of the semiconductor body in the region of the connection contact is less than 5·10¹⁶ cm-3.

21. The semiconductor component of claim 19, comprising wherein the field plate has at least in the region of the connection contact one of the following materials: platinum, platinum silicide, gold, palladium silicide, rhodium silicide, nickel silicide or tungsten silicide.

22. The semiconductor component of claim 19, comprising wherein the field plate has at least in the region of the connection contact a doped polycrystalline semiconductor material.

23. The semiconductor component of claim 19, comprising wherein the semiconductor body has a side, and the at least one field plate is arranged above the side.

24. The semiconductor component of claim 23, comprising a plurality of field plates arranged at a distance from one another.

25. The semiconductor component of claim 23, comprising wherein a plurality of connection contacts are provided between the field plate and the semiconductor body.

26. The semiconductor component of claim 19, comprising an edge, and the at least one field plate is arranged along the edge.

27. The semiconductor component of claim 19, comprising wherein the semiconductor body has an active component region, and the at least one field plate encloses the active component region in a ring-shaped manner.

28. A semiconductor component comprising:
a semiconductor body;
at least one field plate;
a voltage limiting arrangement arranged between the field plate and the semiconductor body and serving for limiting a voltage difference between the at least one field plate and the semiconductor body.

29. The semiconductor component of claim 28, comprising wherein the voltage limiting arrangement has a Schottky contact formed between the field plate and the semiconductor body.

30. The semiconductor component of claim 28, comprising wherein the voltage limiting arrangement has a tunnel dielectric layer formed between the field plate and the semiconductor body.

31. The semiconductor component of claim 28, comprising wherein the field plate is composed of a metal or of a doped polycrystalline semiconductor material.

32. The semiconductor component of claim 28, comprising wherein the semiconductor body has a side, and the at least one field plate is arranged above the side.

33. The semiconductor component of claim 32, comprising a plurality of field plates arranged at a distance from one another.

34. The semiconductor component of claim 128 comprising an edge, and in which the at least one field plate is arranged along the edge.

35. The semiconductor component of claim 28, comprising wherein the semiconductor body has an active component region, and the at least one field plate encloses the active component region in a ring-shaped manner.

36. An integrated circuit including semiconductor component comprising:
a semiconductor body including a first doped semiconductor zone and a second doped semiconductor zone;
a field plate contacting the semiconductor body at a connection contact; and
wherein the semiconductor body has in a region of the connection contact a doping concentration that is less than 5·10¹⁷ cm-b 3.

37. The integrated circuit of claim 36, comprising wherein the field plate contacts the semiconductor body at the first doped semiconductor zone.

38. The integrated circuit of claim 36, comprising wherein the first doped semiconductor zone is doped complementarily to the second doped semiconductor zone.

39. A method of making a semiconductor component comprising:
providing a semiconductor body including a first doped semiconductor zone and a second doped semiconductor zone;
contacting the semiconductor body at a connection contact with a field plate, wherein the semiconductor body has in a region of the connection contact a doping concentration that is less than 5·10¹⁷ cm-3.

40. The method of claim 39, comprising wherein the field plate contacts the semiconductor body at the first doped semiconductor zone.

41. An integrated circuit including a semiconductor component comprising:
a semiconductor body including an active component region;
means for providing a field plate contacting the semiconductor body at a connection contact; and
wherein the semiconductor body has in a region of the connection contact a doping concentration that is less than 5·10¹⁷ cm-3.
